(19) United States
(12) Patent Application Publication
(10) Pub. No.: US 2022/0229474 A1
(43) Pub. Date: Jul. 21, 2022

(54) CARD RETAINERS

(71) Applicant: Hewlett-Packard Development Company, L.P., Spring, TX (US)

(72) Inventors: Xiang Ma, Spring, TX (US); Chan Woo Park, Spring, TX (US); Baosheng Zhang, Spring, TX (US); Richard S. Lin, Spring, TX (US); Fangyong Dai, Spring, TX (US)

(73) Assignee: Hewlett-Packard Development Company, L.P., Spring, TX (US)

(21) Appl. No.: 17/614,592

(22) PCT Filed: Sep. 25, 2019
(86) PCT No.: PCT/US2019/052866

§ 371 Date: Nov. 29, 2021

(51) Int. Cl. G06F 1/18; H05K 7/14

(52) U.S. Cl. CPC G06F 1/186; H05K 7/1417

(57) ABSTRACT

In an example, a card retainer may include a pivot mount, a bracket, and a latch hook. The bracket may be movable or pivotable between a released position and a locked position. The bracket may include a bracket pivot, a locking portion, and a cantilevered latch. The locking portion may engage with an expansion card. Further, the cantilevered latch may engage with the latch hook to retain the bracket in the locked position.

### BACKGROUND

Electronic devices, including computing devices, may include expansion cards, system cards, or other components which may provide additional or enhanced functionality to the electronic device. Such components may be engaged with or installed into the electronic device through the use of expansion slots or other connectors. Such slots or connectors may sometimes be disposed within the electronic device and/or be attached to a system board of the electronic device.

### BRIEF DESCRIPTION OF THE DRAWINGS

FIG. 1A is a perspective view of an example card retainer in a released position.

FIG. 1B is a perspective view of an example card retainer in a locked position.

FIG. 2 is a perspective view of an example bracket of an example card retainer.

FIG. 3A is a perspective view of an example computing device having an example card retainer.

FIG. 3B is a perspective cutaway view of an example computing device having an example card retainer.

FIG. 3C is a perspective cutaway view of an example computing device having an example card retainer.

FIG. 3D is a detail perspective view of the example card retainer of FIGS. 3A-3C.

FIG. 3E is a detail perspective view of the example card retainer of FIGS. 3A-3D.

FIG. 3F is a cross-sectional view of the example card retainer of FIGS. 3A-3E, taken along view line 3F-3F of FIG. 3E.

FIG. 3G is detail perspective view of the example card retainer of FIGS. 3A-3F.

### DETAILED DESCRIPTION

Electronic devices, including computing devices, may include expansion cards, system cards, or other components which may provide additional or enhanced functionality to the electronic device. In some situations, such components may be used to supplement existing components of the device, e.g., increase the storage capacity of the electronic device. Such components may be engaged with or installed into the electronic device through the use of expansion slots or other connectors. Such slots or connectors may sometimes be disposed within the electronic device and/or be attached to a motherboard, a riser card, or other type of system board of the electronic device. Such components may have an edge connector having pins such that, upon the edge connector, and thus the component itself, being engaged with a connector or slot of the electronic device, the pins on the edge connector may be engaged with complementary pins in the slot or connector, thereby enabling electronic communication between the system board and the expansion card or component.

In some situations, the edge connector of the system card or component may be disposed on a single edge, or portion thereof, of the component. Thus, upon installation, the expansion card or component may merely be constrained by the engagement of the edge connector with the slot or connector of the system board, thereby leaving the other edges of the system card free or cantilevered along the system board. This may create an insecure attachment of the system card to the system board, wherein the system card may wobble, vibrate, or otherwise move or loosen from the connector or slot, thereby negatively affecting the function of the card.

A system card may have a first end comprising the edge connector, and a second end opposite the first end. In some situations, the second end may be referred to as a free end, since it is not engaged with the connector or slot. The free end may be fixed or constrained to the system board or another component of the electronic device by a fastener so as to provide a more secure attachment of the system card to the device. Such fasteners may directly or indirectly secure the free end of the system card to an aperture, a mounting standoff, or other fastening or attachment feature of the system board or other component. However, a tool such as a screw driver may be used to install and remove the fastener from the attachment feature, and thus from fixing the free end of the expansion card in place. Therefore, anytime a user may wish to install, swap, upgrade, or otherwise add or remove an expansion card to a computer system, the user may have to have a tool capable of installing and removing the fastener. This may be inconvenient to the user. Additionally, tools may be too large to access certain interior portions of a computing device, making installing or removing an expansion card very difficult. Therefore, it may be desirable for an electronic device, or a system board thereof, to have a simple way of securely fastening and removing a system card or supplemental component to or from the system board that may omit the need for tools.

Implementations of the present disclosure provide an apparatus that may securely attach a system card or other supplemental component to an electronic device, or a system board thereof. Further, examples described herein may be able to secure a free end of an expansion card to a system board or other component without the use of a tool.

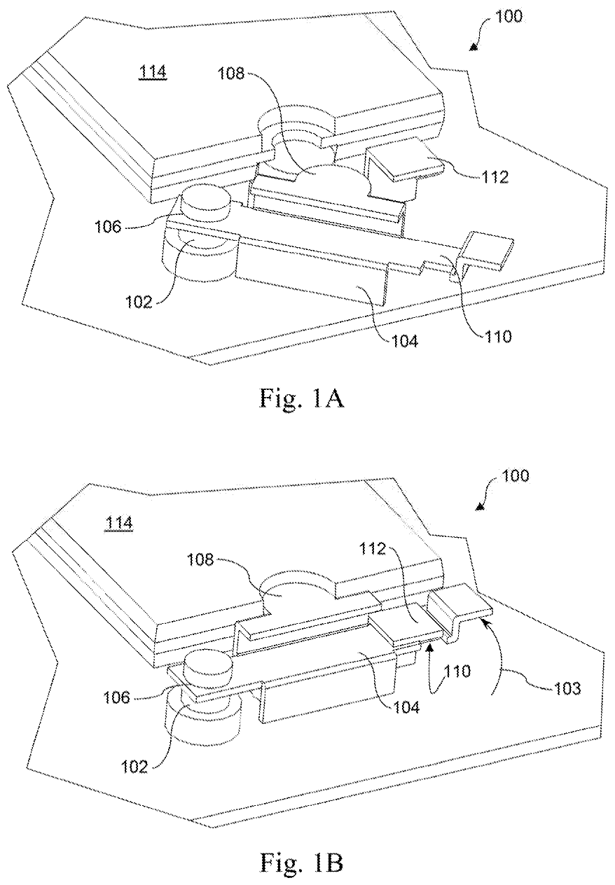

Referring now to FIG. 1A, a perspective view of an example card retainer 100 is illustrated wherein the card retainer 100 is in a released position. The card retainer 100 may include a pivot mount 102, a bracket 104, and a latch hook 112. The bracket 104 may be movable or pivotable between a released position (illustrated in FIG. 1A) and a locked position (illustrated in FIG. 1B and discussed below). The bracket 104 may include a bracket pivot 106, a locking portion 108, and a cantilevered latch 110. The locking portion 108 may engage with an expansion card 114. Further, the cantilevered latch 110 may engage with the latch hook 112 to retain the bracket 104 in the locked position.

The pivot mount 102 may be or may be attached to a component of a computing device in which the card retainer 100 is installed or employed. Further, the pivot mount 102 may be an aperture for receiving a fastener, or may be a protrusion about which another component may rotate or pivot. In some implementations, the pivot mount 102 may include a standoff on to which the bracket 104 may be installed.

The bracket 104 may be a rigid or semi-rigid member capable of holding an expansion card 114 to a surface when the bracket 104 is sufficiently held in place itself. In some implementations, the bracket 104 may be a unitary component having both the locking portion 108 and the cantilevered latch 110 be portions of the bracket 104. In other implementations, the bracket 104 may be a connecting member, on to which separate components locking portion 108 and cantilevered latch 110 may be assembled or attached. Thus, the bracket 104 may be a component that engages the locking portion 108 and the cantilevered latch 110 with the pivot mount. In some implementations, the bracket 104 may be sufficiently rigid or firm such that, if the cantilevered latch 110 is held in place, the locking portion 108 may be able to exert enough holding force or tension on to an expansion card 114, or a portion thereof, so as to hold the expansion card 114, or the portion thereof, in place. In some implementations, the bracket 104 may be constructed of a metallic material, such as sheet or spring steel. In other implementations, the bracket 104 may be constructed of a polymer material and formed through plastic injection molding.

The card retainer 100, or the bracket 104 thereof, may also include a bracket pivot 106. The bracket pivot 106 may engage with the pivot mount 102 so as to enable the bracket to pivot or rotate about the pivot mount 102. In some implementations, the bracket pivot 106 may be a window, aperture, or other opening, and may receive a protrusion of the pivot mount 102. In other implementations, the bracket pivot 106 may be a protrusion or peg and may insert into and be received by the pivot mount 102 to accomplish the rotatability of the bracket 104. In yet further implementations, both the pivot mount 102 and the bracket pivot 106 may be openings, and both may receive a fastener or other intermediary component to accomplish the rotatability of the bracket 104.

The locking portion 108 of the card retainer 100, or bracket 104 thereof, may be a tab, shelf, panel, or other protrusion extending from the bracket 104. The locking portion 108 may be sized and structured so as to positively engage with an expansion card 114, or a portion thereof (e.g., a free end of the expansion card 114), to removably fix or hold the expansion card 114, or free end thereof, securely to a substrate or computing device portion adjacent to the expansion card 114.

Referring now to FIG. 1B, a perspective view of example card retainer 100 is illustrated wherein the card retainer 100 is in a locked position. For example, the bracket 104 of the card retainer 100 may have been pivoted or rotated about the pivot mount 102 (by way of the bracket pivot 106) along example direction 103, which may be a locking direction. Moving the bracket 104 in such a way may engage the bracket 104 with the expansion card such that the locking portion 108 presses on or otherwise positively engages a portion of the expansion card 114 or a free end thereof. Such engagement of the bracket 104 and the expansion card 114 may hold the expansion card 114 in position securely. Stated differently, the bracket 104 may fasten the expansion card 114 in an installed position when the locking portion 108 is engaged with the expansion card 114 in the locked position.

Further, upon the bracket 104, and thus the card retainer 100, being disposed in the locked position as shown, the cantilevered latch 110 may engage with the latch hook 112 so as to hold the card retainer 100 in such a locked position. The cantilevered latch 110 may be a resilient member or a member capable of undergoing elastic deformation, and may be attached to or assembled on to the bracket 104. In some implementations, the cantilevered latch 110 may be a unitary portion or part of the bracket 104. In such an example, the cantilevered latch 110 may have a slimmer profile, cross-section, or width, relative to other portions of the bracket 104 so as to give the cantilevered latch 110 resilient or spring-like characteristics, and allow the cantilevered latch 110 to be depressed or deformed relative to the other portions of the bracket 104. The latch hook 112 may be a protrusion or tab extending from a substrate or another component adjacent the expansion card 114 and the bracket 104. The latch hook 112, in some implementations, may be stiffer or less prone to elastic deformation that the cantilevered latch 110, such that the cantilevered latch 110 can bend or deform around the latch hook 112 upon the cantilevered latch 110 and the latch hook 112 impacting or interfering with one another. As such, upon the cantilevered latch 110 pressing against the latch hook 112, the latch hook 112 may depress the cantilevered latch 110 in a downward direction until the cantilevered latch 110 is able to move past the latch hook 112 and be retained by the latch hook 112. In this context, downward direction refers to a direction away from the latch hook 112. Similarly, the cantilevered latch 110 may be further depressed (e.g., by a user) to disengage from the latch hook 112, thereby allowing the card retainer 100 to move back from the locked position to the released position and allow the expansion card 114 to be removed from the computing device within which it is disposed.

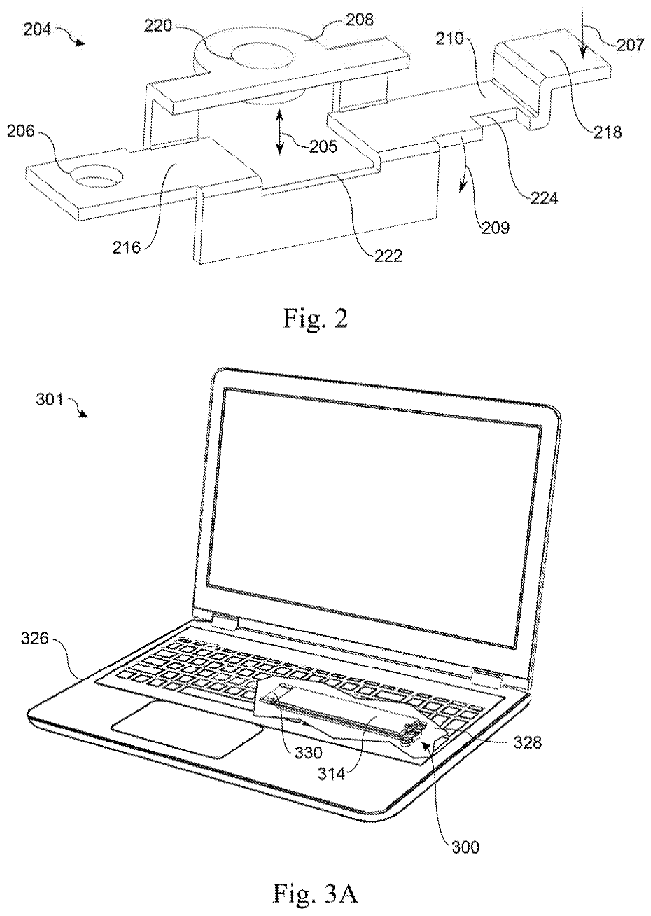

Referring now to FIG. 2, a perspective view of an example bracket 204 of another example card retainer is illustrated. Example bracket 204 may be similar to example bracket 104, described above. Further, the similarly-named elements of example bracket 204 may be similar in function and/or structure to the respective elements of example bracket 204, as they are described above. Example bracket 204 may include a body portion 216, a bracket pivot 206 disposed at a first end of the body portion 216, a cantilevered latch 210 disposed at a second end of the body portion 216, opposite the first end, and a locking portion 208 extending from the body portion 216 in between the first end and the second end. The locking portion 208 may engage with a mounting portion of an expansion card (not shown).

The body portion 216 may be a rigid or semi-rigid component that may provide mechanical support for the other constituent portions of the bracket 204. Specifically, the body portion 216 may connect the cantilevered latch 210 and the locking portion 208 with the bracket pivot 206, and may also spatially fix the cantilevered latch 210 and the locking portion 208 relative to one another. In some implementations, the body portion 216, the bracket pivot 206, the cantilevered latch 210, and the locking portion 208 may all be constructed of a single unitary component, e.g., a stamped and/or bent or otherwise formed sheet metal component. In other implementations, such a unitary construction may comprise a polymer material such as injection molded plastic.

The bracket pivot 206, while illustrated as an aperture, window, or opening to receive a post or fastener, may instead be a post, pin, or other protrusion in other implementations. Stated differently, the bracket pivot 206 may have a suitable structure so as to enable rotation of the bracket 204 relative to another component of a computing device within which the bracket 204 of the example card retainer is employed or installed.

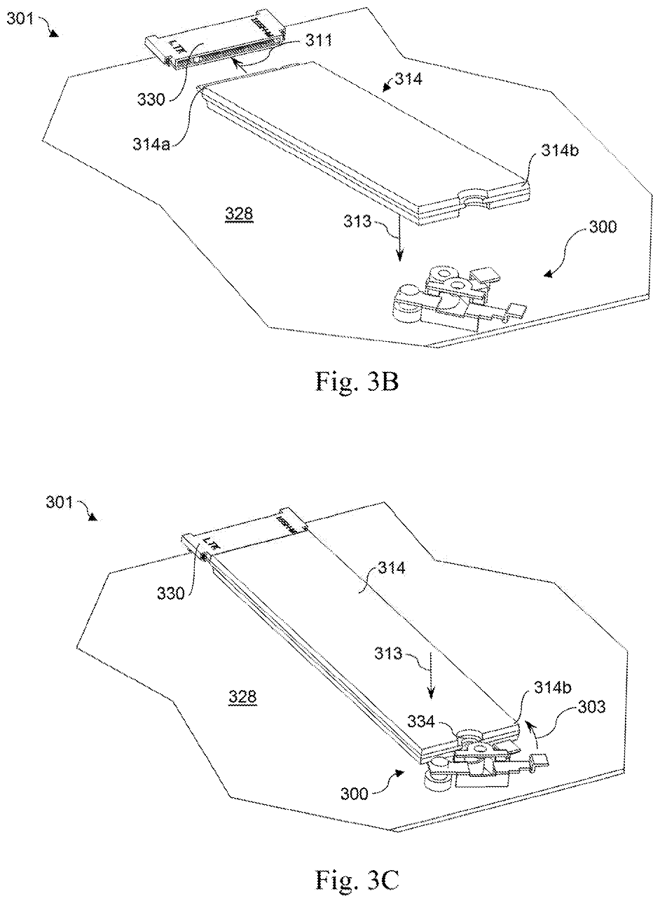

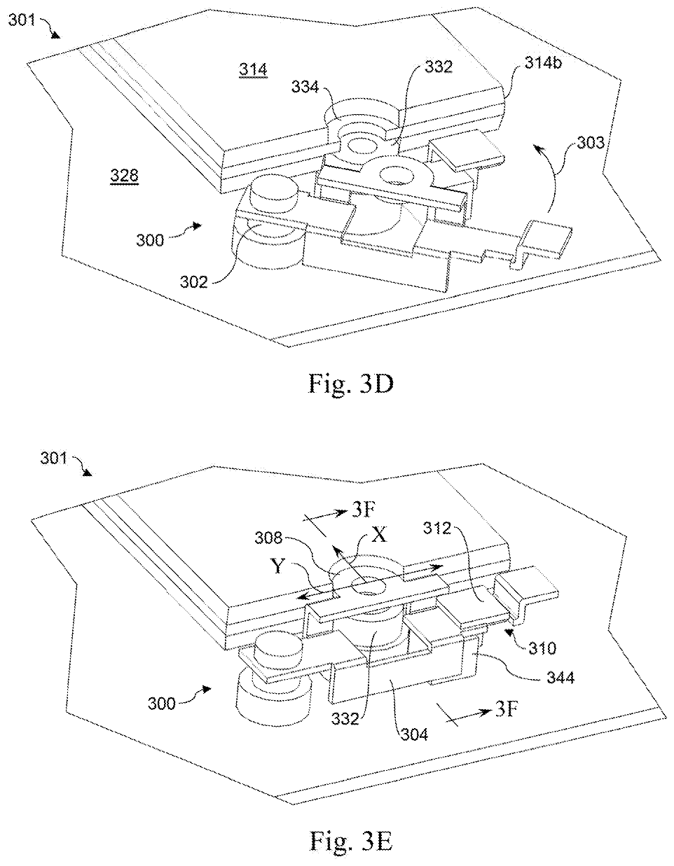

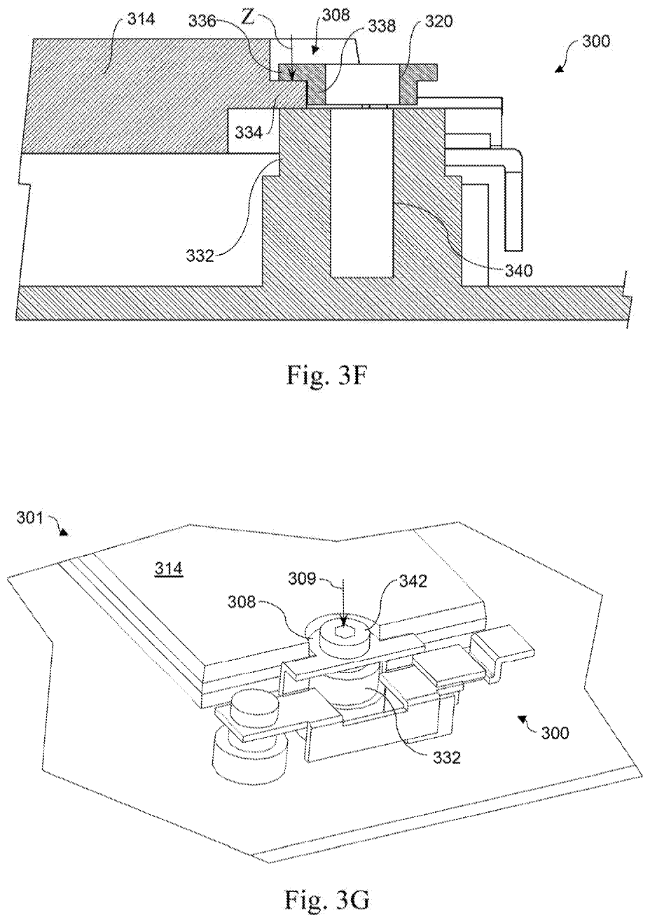

In some implementations, the bracket 204 may further include a cutout 222 adjacent the locking portion 208. When the locking portion 208 is engaged with a mounting portion of an expansion card, the mounting portion may be disposed near, adjacent, or abutting against a mounting standoff. As will be discussed further below with reference to FIGS. 3D-3F, the cutout 222 may be formed, sized, and/or located on the body portion 216 sufficiently close to and adjacent to the locking portion 208 such that the cutout 222 is able to receive the mounting standoff and provide clearance for such mounting standoff when the locking portion 208 is engaged with the mounting portion of the expansion card. Additionally, the locking portion 208 may be spaced from the cutout 222, e.g., along direction 205, such that, upon the cutout 222 receiving the mounting standoff, the locking portion 208 is disposed adjacent the mounting standoff.

In some implementations, the bracket 204 may further include a fastener opening 220 to receive a fastener (not shown). The fastener opening 220 may be a channel or other suitable opening extending through an entire thickness of the locking portion 208 such that the fastener may be inserted through the fastener opening and thus through the locking portion 208. The fastener may be installed into the fastener opening to fix the bracket 204, and thus the locking portion 208, in position relative to an expansion card, as will be discussed further below with reference to FIG. 3G.

The bracket 204, or the body portion 216 thereof, may further include a notch 224, in some examples. The notch 224 may be a cutout or indent disposed in the cantilevered latch 210. In such examples, the notch 224 may engage with a latch hook (not shown) disposed on another component of a computing device within which the bracket 204 is installed or employed as a part of a card retainer.

In yet further implementations, the bracket 204, or the cantilevered latch 210 thereof, may include a tab 218 extending from the second end of the body 216. The tab 218, upon being depressed, e.g., along direction 207 in the illustrated example, may cause the cantilevered latch 210 to depress or bend relative to the other portions of the bracket 204, e.g., along direction 209. Such deformation or depression may be enabled by the cantilevered nature of the cantilevered latch 210, as extending from the second end of the body 216 while lacking support at a distal end of the cantilevered latch 210. Further, such depression of the cantilevered latch 210 may enable the cantilevered latch 210, or the notch 224, to become disengaged from a latch hook, and therefore enabling the bracket 204 to move or rotate about the bracket pivot 206.

Referring now to FIG. 3A, a perspective view of an example computing device 301 having an example card retainer 300 is illustrated. Example card retainer 300 may be similar to other example card retainers described above. Further, the similarly-named elements of example card retainer 300 may be similar in function and/or structure to the respective elements of other example card retainers, as they are described above.

Computing device 301 may include a housing or enclosure 326. The enclosure 326 may electrically and mechanically support and/or house components of the computing device 301. Such components may include processors, storage drives, memory, power supplies, or other suitable components for use with a computing device 301. In some implementations, the computing device 301 may include a system board 328 disposed within the enclosure 326. The system board 328 may include a printed circuit board (PCB) and may be a mother board or another type of circuit board. In some examples, the system board 328 may include an expansion connector 330 to receive and operable engage with an expansion card 314. The expansion connector 330 may include pins, pads, contacts, or other components to electrically and/or mechanically engage with the expansion card 314, or an edge connector or other portion thereof.

The expansion card 314 may be a component to enhance or improve the functionality of the computing device 301, in some implementations. In other examples, the expansion card 314 may be a component to support the nominal or ordinary function of the computing device 301. The expansion card 314 may be a storage drive, a memory, a graphics card, a network card, or another type of computing component that may engage with an expansion connector 330. In some implementations, the expansion card 314 may include an edge connector to mechanically and electrically engage with the expansion connector 330 such that the computing device 301 can electrically communicate with the expansion card 314. In some examples, the expansion card 314 may be a flash memory or flash storage drive such as an M.2 form factor storage drive. In other examples, the expansion card 314 may be a storage drive of a different form-factor or specification.

Computing device 301 may be a notebook computer or mobile workstation, in some examples. In other examples, computing device 301 may be another type of computing device, such as a desktop computer, a server and/or server rack, an imaging device such as a printer or copier, or an additive manufacturing machine (e.g., three-dimensional (3D) printer). In yet other examples, computing device 301 may be another type of electronic device that may include an expansion card 314 and/or an expansion connector 330.

Referring now to FIG. 3B, a perspective cutaway view of example computing device 301 is illustrated, wherein the enclosure is omitted for clarity. The computing device 301 is illustrated as having the expansion card 314 not engaged with the expansion connector 330. The expansion card 314 may include a first end 314a, sometimes referred to as a connector end, which may include an edge connector that is mechanically and electrically complementary to the expansion connector 330. When the expansion card 314 is engaged with the expansion connector 330, and thus the computing device 301, the computing device 301 may electrically communicate with the expansion card 314 via the expansion connector 330 and the edge connector of the expansion card 314.

In order to install or engage the expansion card 314 with the expansion connector 330, and thus the computing device 301, the first end 314a of the expansion card 314 may be inserted into the expansion connector 330, e.g., along direction 311. Further, the expansion card 314 may be pivoted downward along example direction 313 towards a substrate on which the expansion connector 330 may be disposed, e.g., a system board 328. The expansion card 314 may additionally include a second end 314b, sometimes referred to as a free end, opposite the first end 314a. Referring additionally to FIG. 3C, a perspective cutaway view of the computing device 301 is illustrated wherein the expansion card 314 is engaged with the expansion connector 330. The first end 314a is engaged with the expansion connector 330, and the expansion card 314 has moved along example direction 313 to securely and fully seat the edge connector into the expansion connector 330. As such, the expansion card 314 now extends from the expansion connector 330 in a cantilevered fashion. As such, the second end 314b is considered a free end. The second end 314 may thus include a mounting portion 334 in order to secure the second end 314b to the substrate (e.g., the system board 328), and eliminate the cantilevered nature of the second end 314b. The card retainer 300 may be movable between a released position (illustrated in FIG. 3C) and a locked position, e.g., along direction 303, in order to secure the second end 314b of the expansion card 314.

Referring now to FIG. 3D, a detail perspective view of the example card retainer 300 of the example computing device 301 is illustrated. The card retainer 300 is disposed in a released position, and the expansion card 314 is illustrated as operably engaged with the expansion connector 330 (not shown in FIG. 3D). In this context, operably engaged refers to the expansion card 314 being inserted into the expansion connector 330 to a sufficient degree that the computing device 301 can electrically communicate with the expansion card 314 via the expansion connector 330. In some implementations, the computing device 301, or the system board 328 (or other substrate or component of the computing device 301 in other examples) thereof, may include a mounting standoff 332 to support, at least partially, the second end 314b of the expansion card 314 when the expansion card 314 is engaged with the expansion connector 330. The mounting standoff 332 may be a block, post, lug, or other protrusion extending from the system board 328 or an intermediary component (or another component of the computing device 301 in other examples) to a sufficient degree such that the second end 314b, or a portion thereof, may mate or rest upon the mounting standoff 332. Thus, the mounting standoff 332 may help alleviate the cantilevered nature of the expansion card 314 when it is engaged with the expansion connector 330. In the illustrated example, the expansion card 314 may include a mounting portion 334 to mate with or engage with the mounting standoff 332. The mounting portion 334 may be a cutout in the expansion card 314, in some examples. In order to further secure the expansion card 314 in its operably engaged state with the expansion connector 330, the card retainer 300 may be movable about a pivot mount 302 disposed on the system board 328, or on an intermediary component, along example direction 303 from the released position to a locked position.

Referring additionally to FIG. 3E, a detail perspective view of the example card retainer 300 is illustrated wherein the card retainer 300, or a bracket 304 thereof, is disposed in a locked position. When the bracket 304 is in the locked position, the card retainer 300 may be engaged with the mounting portion 334 of the expansion card 314 so as to removably fix or hold in place the expansion card 314 to the system board 328. The bracket 304 may be moved between the released position and the locked position without the use of any tools. Thus, a user may just manually rotate the bracket 304 to the locked position to lock or securely hold the expansion card 314 in its engaged state.

The card retainer 300 may hold or secure the expansion card 314 by a locking portion 308 of the card retainer 300 engaging with the mounting portion 334 of the expansion card 314 when the bracket is in the locked position. In some examples, the locking portion 308 may have a structure or profile that matches or is complementary to the structure of the mounting portion 334. As such, when the card retainer 300 or the bracket 304 thereof is moved into the locked position, the locking portion 308 may mate with and/or nest or insert into the mounting portion 334. By doing so, the locking portion 308 may engage or lock with the expansion card 314, or the mounting portion 334 thereof, in an X-direction and a Y-direction, as illustrated in FIG. 3E. In some examples, an X-direction may refer to a direction substantially aligned with a length of the expansion card 314, and a Y-direction may refer to a direction substantially aligned with a width of the expansion card 314, as illustrated. The locking portion 308 may also lock with the expansion card 314, or the mounting portion 334 thereof, in a Z-direction, as illustrated in FIG. 3F and discussed below. A Z-direction may refer to a direction along a thickness or depth of the expansion card 314. In some implementations, the locking portion 308 and the mounting portion 334 may have rounded or semi-circular profiles or shapes such that, when the locking portion 308 is engaged with the mounting portion 334 and mated along their shared or complementary circumference, the expansion card 314 is held in place at its second end 314b in both the X-direction and the Y-direction. In other examples, the locking portion 308 and the mounting portion 334 may have other complementary shapes or profiles to limit movement of the expansion card 314 in such directions.

The card retainer 300 may also have a cantilevered latch 310 extending from the bracket 304. The cantilevered latch 310 may engage with or latch on to a latch hook 312. The latch hook 312 may be fixed relative to the system board 328. In some implementations, the latch hook 312 may have an overhanging structure, so as to engage with the cantilevered latch 310 from above. As such, the latch hook 312 may include a tooth extending down from the latch hook 312 in a direction towards the cantilevered latch 312 and may engage with a notch of the cantilevered latch 310. It should be noted that other structures of the latch hook 312 are contemplated, e.g., in some examples the latch hook 312 may be disposed underneath the cantilevered latch 310 and have a tooth extending upwards toward the cantilevered latch 310 and/or the notch thereof. Upon latching on to the latch hook 312, the cantilevered latch 310 may hold or lock the bracket 304, and thus the card retainer 300 as a whole, in the locked position. The cantilevered latch 310 may be a resilient and elastically deformably (i.e., depressable) member. As such, in order to disengage the cantilevered latch 310 from the latch hook 312, it may be depressed (e.g., by a user intending to remove the expansion card 314) so as to push or deform the cantilevered latch 310 in a direction away from engagement with the latch hook 312. In examples wherein the latch hook 312 is underneath the cantilevered latch 310, the cantilevered latch 310 may be pulled upwards away from engagement with the latch hook 312 in order to unlock the cantilevered latch 310. Once clear from the latch hook 312, the cantilevered latch 310 may no longer hold the bracket 304, and thus the card retainer 300, in the locked position, and the bracket 304 may be moved about the pivot mount 302 to transition to the released position (e.g., along a direction opposite to direction 303).

In some implementations, the card retainer 300 may further include a support lug 344. The support lug 344 may be disposed near or adjacent to the cantilevered latch 310 and may be fixed relative to the system board 328 (or other substrate on to which the expansion card 314 and card retainer 300 are installed). The support lug 344 may engage with the cantilevered latch 310 when the bracket 304 is in the locked position. In some implementations, the support lug 344 may be disposed in between the cantilevered latch 310 and the system board 328 so as to limit the amount of depression that the cantilevered latch 310 is able to undergo. This may prevent the cantilevered latch 310 from being over-depressed (e.g., by a user) and breaking or plastically deforming to the point where the cantilevered latch 310 is unable to be engaged with the latch hook 312.

Referring now to FIG. 3F, a cross-sectional view of the example card retainer 300 is illustrated as taken along view line 3F-3F of FIG. 3E. FIG. 3F illustrates the card retainer 300 and the bracket 304 thereof as being disposed in the locked position. The locking portion 308 is engaged with the mounting portion 334 of the expansion card 314. When the bracket 304 is in the locked position, securing the expansion card 314 in place, the locking portion 308 may be disposed adjacent to the mounting standoff 332. As such, when the bracket 304 is in the locked position, the locking portion 308 may compress or tighten the mounting portion 334 of the expansion card 314 against a top surface of the mounting standoff 332 in order to alleviate the cantilevered nature of the expansion card 314 and secure the expansion card 314 in place. As such, the locking portion 308 may secure and lock the expansion card 314, and/or the mounting portion 334 thereof, along a Z-direction, as illustrated. As such, the locking portion 308 may secure the free end of the expansion card along all three available dimensions or directions of movement (X, Y, Z), providing a secure installation of the expansion card 314.

In some implementations, the locking portion 308 may include a flange 336 and a boss 338 extending from the flange 336. The flange may extend at least partially around an outer periphery of the locking portion 308, and when in the locked position, may rest on and/or push against a top surface of the mounting portion 334 to secure the free end against movement in an upwards (i.e., a disengaging) direction. The boss 338 may rest inside and/or push against an inner circumference or other surface of the mounting portion 334 to secure against lateral and longitudinal movement of the free end of the expansion card 314.

Referring additionally to FIG. 3G, another detail perspective view of the example card retainer 300 is illustrated, wherein the card retainer 300 further includes a fastener 342. In some implementations, the locking portion 308 may include a fastener opening 320 to receive a fastener 342. The fastener opening 320 may be a channel or opening extending through a thickness of the locking portion 308. When the card retainer 300 is disposed in the locked position and the locking portion 308 is disposed adjacent to the mounting standoff 332, the fastener opening 320 may be aligned with a receptacle 340 extending into the mounting standoff 332. The receptacle 340, in some examples, may be a threaded opening or may have a threaded insert disposed within the receptacle 340 to engage with complementary threads on a fastener 342. Thus, while the example card retainer 300 provides an easy, secure, and tool-free way to secure an expansion card 314 inside a computing device 301, a user may still sometimes desire an extra level of security for the expansion card 314. This may sometimes be desired when the computing device 301 is a mobile computing device such as a notebook or mobile workstation, and/or the computing device 301 is subject to movement, shock, or other external forces. Accordingly, a user can employ a fastener 309, e.g., a screw, bolt, pin, or other suitable fastener, and insert such fastener through the fastener opening 320 and into the receptacle 340 within the mounting standoff 332, e.g., along insertion direction 309, to fix the locking portion 308 to the mounting standoff 332 to further secure the card retainer 300 in the locked position, and thus securing the expansion card 314 in its installed position.

What is claimed is:

1. A card retainer, comprising:
a pivot mount;
a bracket movable between a released position and a locked position, comprising:
a bracket pivot to engage with the pivot mount;
a locking portion to engage with an expansion card; and
a cantilevered latch; and
a latch hook, the cantilevered latch to engage with the latch hook to retain the bracket in the locked position.

2. The card retainer of claim 1, wherein the bracket is to fasten the expansion card in an installed position when the locking portion is engaged with the expansion card in the locked position.

3. The card retainer of claim 2, wherein the locking portion is to lock with the expansion card in an X-direction, a Y-direction, and a Z-direction.

4. The card retainer of claim 1, wherein the cantilevered latch is a resilient member able to be depressed to disengage from the latch hook.

5. The card retainer of claim 4, further including a support lug to engage with the cantilevered latch when the bracket is in the locked position, the support lug to limit an amount of depression of the cantilevered latch.

6. The card retainer of claim 1, wherein the locking portion includes a fastener opening to receive a fastener, the fastener to fix the bracket in the locked position.

7. A bracket for a card retainer, comprising:
a body portion;
a bracket pivot disposed at a first end of the body portion;
a cantilevered latch disposed at a second end of the body portion, opposite the first end; and
a locking portion extending from the body portion in between the first end and the second end, the locking portion to engage with a mounting portion of an expansion card.

8. The bracket of claim 7, wherein the locking portion includes a flange and a boss extending from the flange, the boss and the flange to engage with the mounting portion in an X-direction, a Y-direction, and a Z-direction.

9. The bracket of claim 7, wherein the body includes a cutout adjacent the locking portion to receive a mounting standoff of a system board.

10. The bracket of claim 9, wherein the locking portion is spaced from the cutout such that, upon the cutout receiving the mounting standoff, the locking portion is disposed adjacent the mounting standoff.

11. The bracket of claim 7, wherein the body portion includes a notch disposed in the cantilevered latch, the notch to engage with a latch hook disposed on a system board.

12. The bracket of claim 7, wherein the cantilevered latch includes a tab extending from the second end of the body, the tab, upon being depressed, to cause the cantilevered latch to depress.

13. A computing device, comprising:
an enclosure;
a system board disposed within the enclosure and having an expansion connector;
an expansion card operably engaged with the expansion connector at a first end and having a mounting portion at a second end, opposite the first end; and
a card retainer to engage with the mounting portion to removably fix the expansion card to the system board, the card retainer including:
a pivot mount disposed on the system board;
a bracket having a bracket pivot engaged with the pivot mount such that the bracket is movable between a released position and a locked position;
a locking portion to engage with the mounting portion when the bracket is in the locked position; and
and a cantilevered latch.

14. The computing device of claim 13, wherein the locking portion is disposed adjacent to a mounting standoff when the bracket is in the locked position.

15. The computing device of claim 14, wherein the locking portion further comprises a fastener opening to receive a fastener, the fastener to fix the locking portion to the mounting standoff.
